(19) United States
(12) Patent Application Publication
(10) Pub. No.: US 2001/0040246 A1
(43) Pub. Date: Nov. 15, 2001

(54) GaN field-effect transistor and method of manufacturing the same

(76) Inventor: Hirotatsu Ishii, Yokohama-shi (JP)

Correspondence Address: KNOBBE MARTENS OLSON & BEAR LLP, 620 NEWPORT CENTER DRIVE, SIXTEENTH FLOOR, NEWPORT BEACH, CA, 92660, US

(21) Appl. No.: 09/784,833

(22) Filed: Feb. 16, 2001

(30) Foreign Application Priority Data
Feb. 18, 2000 (JP) 2000-41555

(51) Int. Cl. H01L 31/0328; H01L 31/0336; H01L 21/4763; H01L 21/336; H01L 31/072; H01L 21/3205

(52) U.S. Cl. 257/192; 257/194; 438/285; 438/590

(57) ABSTRACT

There are provided a GaN field effect transistor (FET) exhibiting an excellent breakdown voltage owing to the high quality of GaN crystal in a region where the electric lines of force concentrate during operation of the same, and a method of manufacturing the same. The FET has a layer structure formed of a plurality of GaN epitaxial layers. A gate electrode and a source electrode are disposed on the surface of the layer structure, and a drain electrode is disposed on the reverse surface of the same. A region of the layer structure in which the electric lines of force concentrate during operation of the FET has a reduced dislocation density compared with the other regions in the layer structure. The GaN FET is manufactured by forming, on a crystal-growing substrate having a surface formed with a plane pattern of a material other than a GaN-based material in an identical design to a plane pattern of an electrode determining the region in which the electric lines of force concentrate, a plurality of GaN epitaxial layers, one upon another, by using the epitaxial lateral overgrowth technique, thereby forming a layer structure, and then forming operational electrodes on the surface of the layer structure.

### BACKGROUND OF THE INVENTION

1. Field of the Invention

The present invention relates to a GaN field-effect transistor and a method of manufacturing the same, and more particularly to a GaN field-effect transistor which exhibits excellent operating characteristics, such as high breakdown voltage, due to decreased dislocation density in a GaN crystal forming a region in which the electric lines of force concentrate during operation of the transistor and regions laterally adjacent thereto, as well as to a method of manufacturing the GaN field-effect transistor by using the epitaxial lateral overgrowth technique.

2. Prior Art

A field effect transistor (FET) using a GaN-based material is capable of operating without causing thermal runaway even under an environmental temperature of nearly 400° C., and hence draws much attention as a high-temperature operative solid-state component.

When a GaN-based material is used, differently from a case where an Si crystal, a GaAs crystal or an InP crystal is employed, it is difficult to produce a single-crystal substrate having a large diameter, which makes it impossible to form an FET-layer structure by epitaxially growing a predetermined crystal layer on a GaN single-crystal substrate. For this reason, in manufacturing a GaN FET, the following method is employed for growing a crystal of a GaN-based material. Now, the method will be described by taking a horizontal current path GaN FET schematically shown in FIG. 1 as an example.

First, a single-crystal substrate 1 formed of a material, such as sapphire, SiC, Si, GaAs or GaP, is prepared as a substrate for use in crystal growth.

Then, a GaN film is preliminarily formed on the substrate 1 by the epitaxial growth technique, such as MOCVD. Although the lattice constant of a substrate formed of any one of the above-mentioned materials is quite different from that of a GaN single crystal, appropriate selection of film-forming conditions (e.g. growth temperature) for crystal growth makes it possible to form a low-temperature deposition buffer layer (hereinafter simply referred to as “the buffer layer”) 2 basically formed of a GaN single crystal on the substrate 1.

However, due to a large lattice misfit between the buffer layer 2 and the substrate 1, the buffer layer 2 contains threading dislocations (defects) that extend generally vertically in a direction of film thickness. Usually, the dislocation density in the buffer layer 2 is approximately 1×10¹⁰ cm⁻².

Then, a plurality of GaN crystal layers are sequentially deposited, one upon another, on the buffer layer 2 by epitaxial growth of GaN, to thereby form a layer structure 3 for implementing FET functions. Then, electrodes, such as source electrodes S and drain electrodes D forming ohmic contacts to an upper surface of the layer structure 3, and gate electrodes G forming Schottky contacts or MIS (metal-insulator-semiconductor) contacts to the same, are formed on the upper surface of the layer structure 3 by predetermined FET processing, whereby the horizontal current path GaN FET shown in FIG. 1 is manufactured.

In the case of the FET having the layer structure described above, the threading dislocations in the buffer layer 2 extend in a propagating manner into the layer structure 3 of the GaN crystals for implementing the FET functions in the direction of film thickness (i.e. vertically). For instance, there exist about one hundred threading dislocations in a plane of each 1 μm square of the layer structure 3. Therefore, in comparison with its perfect crystal, the GaN crystals forming the layer structure 3 are degraded in quality.

As a result, the GaN FET manufactured by the above method suffers from the following problems:

(1) During operation of the FET, for example, when the FET is in its pinch-off state, the electric lines of force concentrate in a region R in the layer structure including a region R₁ immediately under the gate electrode G as one of the electrodes and a region R₂ adjacent to the region R₁ and spreading laterally toward the drain electrode D side, particularly concentrate in the region R₁. Therefore, if the GaN crystal forming the region R has a low dislocation density and hence a high quality, the region is expected to exhibit a high breakdown voltage. Actually, however, the above FET (FET as shown in FIG. 1) can undergo electrical breakdown at an extremely low field, since there exist numerous threading dislocations in the region R as well.

(2) When a bias voltage is applied to the gate electrode G so as to place the FET in an OFF state in which no current flows between the source electrode and the drain electrode thereof, a considerable amount of leak current can flow between the source electrode S and the drain electrode D.

(3) When the FET is a MESFET type having a Schottky barrier formed in a portion where the gate electrode G is formed, a reverse breakdown voltage of the gate electrode G can be lowered, or a reverse current can be increased.

(4) Further, contact resistance at respective ohmic contacts of the source electrode and the drain electrode to the layer structure 3 increases, and hence effective mobility as the property of the FET decreases, which degrades the driving power of the FET.

As described above, in the conventional GaN FET shown in FIG. 1, the threading dislocations (defects) are produced at a high dislocation density in the GaN crystals having a layer structure, at a location of the region R including the region immediately under the electrode and the region adjacent thereto, causing degradation of the quality of the GaN crystals, which prevents the FET from reaching its full potential of performance intended by the design.

### OBJCETS AND SUMMARY OF THE INVENTION

It is an object of the present invention to provide a high-performance GaN FET constructed to have a GaN crystal layer structure having a portion for an FET function in which dislocation density of GaN crystals is largely decreased, thereby allowing the FET to exploit the full potential of characteristic features of GaN crystals.

It is another object of the present invention to provide a method of manufacturing the high-performance GaN FET, by using the epitaxial lateral overgrowth technique.

To attain the above objects, the present invention provides a GaN field-effect transistor comprising:

a plurality of GaN epitaxial crystal layers in a layer structure; and

at least electrodes necessary for operation of the field-effect transistor being disposed on a surface of the layer structure,

wherein the layer structure has a region having a reduced dislocation density compared with other regions, the region forming the maximum electric field during operation of the field-effect transistor.

The term “the maximum electric field” is used, throughout the specification, to mean a region where the maximum electric field appears when a voltage is applied to the electrodes so as to cause the field effect transistor to perform pinch-off operation.

More specifically, there is provided a vertical GaN field-effect transistor (hereinafter referred to as “the FET (1)”),

wherein a source electrode and a gate electrode are formed on the surface of the layer structure, and a drain electrode is formed on a reverse surface of the layer structure, at least a region in the layer structure immediately under the source electrode being formed in GaN epitaxial crystal layer structure to have a decreased dislocation density compared with other regions in the layer structure, and

a horizontal GaN field-effect transistor (hereinafter referred to as “the FET (2)”),

wherein a source electrode, a gate electrode, and a drain electrode are formed on the surface of the layer structure thereon, at least a region in the layer structure immediately under the gate electrode being formed to have a decreased dislocation density compared with other regions in the layer structure.

In either of the above FET's, when the FET is operated, the maximum electric field appears in the region where a channel is formed, and therefore, the quality of crystallinity of this portion of the layer structure has a direct influence on operating characteristics of the FET.

Further, the present invention provides a method of manufacturing a GaN field-effect transistor, comprising the steps of:

forming a plurality of GaN epitaxial crystal layers, one upon another, on a surface of a crystal-growing substrate by using an epitaxial lateral overgrowth technique, thereby forming a layer structure partially including a region having a decreased dislocation density; and

disposing an electrode that enables operation of the field-effect transistor and at the same time determines the maximum electric field region wherein an electric field is concentrated during operation of the field-effect transistor, on a surface of the layer structure in a manner such that the region having a decreased dislocation density and the maximum electric field region coincide with each other,

wherein a mask for epitaxial lateral overgrowth is formed on the surface of the crystal-growing substrate, the mask being formed of a material other than a GaN-based material, with a design pattern identical to a configuration pattern of the electrode.

Further, the present invention provides the method of manufacturing the FET (1), including the steps of:

forming a source electrode and a gate electrode on the surface of the layer structure;

stripping the crystal-growing substrate from the layer structure, thereby causing the laser beam exposure on a reverse surface of the layer structure; and

forming a drain electrode on the reverse surface of the layer structure removed the substrate.

### BRIEF DESCRIPTION OF THE DRAWINGS

FIG. 1 is a cross-sectional view of a conventional GaN FET;

FIG. 2 is a cross-sectional view of an example of a crystal-growing substrate A₁ used in the epitaxial lateral growth (ELO) technique;

FIG. 3 is a cross-sectional view of another crystal-growing substrate A₂;

FIG. 4 is a cross-sectional view showing a state of threading dislocations existing in a GaN crystal layer formed on the crystal-growing substrate A₁;

FIG. 5 is a cross-sectional view showing a basic layer structure of a unit structure U₁ of a vertical FET (1) according to the present invention;

FIG. 6 is a perspective view of a crystal-growing substrate A₁ used for production of the unit structure U₁;

FIG. 7 is a cross-sectional view taken on line VII-VII of FIG. 6;

FIG. 8 is a cross-sectional view showing threading dislocations extending in a slab substrate C manufactured by using the crystal-growing substrate A₁;

FIG. 9 is a cross-sectional view showing a state in which a trench structure for a gate electrode is formed in the slab substrate C;

FIG. 10 is a cross-sectional view showing a state in which an insulating film is formed on the trench structure;

FIG. 11 is a cross-sectional view showing a state in which a gate electrode is formed;

FIG. 12 is a cross-sectional view showing a state in which source electrodes are formed;

FIG. 13 is a cross-sectional view showing a basic layer structure of a unit structure U₂ of a vertical GaN MISFET according to the present invention;

FIG. 14 is a cross-sectional view showing a basic layer structure of a unit structure U₃ of a bipolar transistor according to the present invention;

FIG. 15 is a cross-sectional view showing a basic layer structure of a unit structure U₄ of a horizontal GaN MESFET according to the present invention;

FIG. 16 is a perspective view of a crystal-growing substrate A₃ used for production of the unit structure U₄;

FIG. 17 is a cross-sectional view showing a basic layer structure of a unit structure U₅ of a horizontal GaN HEMT (or MISFET) according to the present invention;

FIG. 18 is a cross-sectional view of a vertical FET designed in Example 1;

FIG. 19 is a perspective view of a crystal-growing substrate A₄ used for production of the designed FIG. 18 vertical FET;

FIG. 20 is a cross-sectional view of a slab substrate C₁ manufactured by using the crystal-growing substrate A₄;

FIG. 21 is a cross-sectional view showing a state in which trench structures for gate electrodes are formed in the slab substrate C₁;

FIG. 22 is a cross-sectional view showing a state in which the trench structures each having an insulating film formed thereon and windows for turn-off junctions owing to the minority carrier rejection are formed;

FIG. 23 is a cross-sectional view showing a state in which gate electrodes and the turn-off junctions are formed;

FIG. 24 is a cross-sectional view showing a state in which a source metal is formed;

FIG. 25 is a cross-sectional view showing a state in which a heat sink is formed and the crystal-growing substrate is stripped;

FIG. 26 is a cross-sectional view of a horizontal FET designed in Example 2;

FIG. 27 is a cross-sectional view of a crystal-growing substrate As used for manufacturing the designed FIG. 26 horizontal FET;

FIG. 28 is a cross-sectional view of a slab substrate C₂ manufactured by using the crystal-growing substrate A₅;

FIG. 29 is a cross-sectional view showing the slab substrate C₂ having source electrodes and drain electrodes formed thereon in a design pattern; and

FIG. 30 is a cross-sectional view showing a state in which gate electrodes are formed in a design pattern.

### DETAILED DESCRIPTION OF THE INVENTION

First, the process of development of the present invention will be described.

A preconditional problem to be solved in the present invention is that in the GaN FET manufactured by the conventional method described above, the threading dislocations existing in the buffer layer inevitably extend in a propagating manner into the GaN crystal layers which implement FET functions, and thereby degrade the quality of the GaN crystal layers. This impairs a high breakdown field that the GaN crystals inherently have, which results in degraded performance of the FET formed of the GaN crystals, for example, in respect of electric field, in comparison with the design characteristics.

In the course of a research process for solving the above problem, the present inventor paid his attention to the epitaxial lateral overgrowth (ELO) method (see Applied Physics of Japan, vol. 68, No. 7, PP. 774-779, 1999).

In the ELO technique, a substrate A₁ shown in FIG. 2 or a substrate A₂ shown in FIG. 3 are used as a crystal-growing substrate for growing GaN crystals thereon.

The substrate A₁ is of a type produced by forming the aforementioned GaN buffer layer 2 on a substrate 1 formed, for example, of a sapphire or Si single crystal, and further forming ELO masks 4 (masks for epitaxial lateral overgrowth) each formed, for example, of SiO₂ on the GaN buffer layer 2 in a stripe pattern. On the other hand, the substrate A₂ is of a type formed by once forming the GaN buffer layer 2 on the substrate 1, and then removing portions of the GaN buffer layer 2 by etching to cause a surface 1a of the substrate 1 to be exposed in a stripe pattern.

Therefore, on the upper surface of each of the substrates A₁ and A₂, there are formed a stripe pattern of a GaN crystal and another stripe pattern of a material (SiO₂ in the case of the substrate A₁ and a material forming the substrate 1 in the case of the substrate A₂) other than a GaN crystal in a coexisting manner.

It should be noted that the GaN buffer layer 2 on each of the substrates A₁, A₂ has the numerous threading dislocations 2A extending in the direction of film thickness.

When epitaxial crystal growth is performed on the substrate A₁ or A₂ under appropriate film-forming conditions, vertical crystal growth proceeds, and at the same time, lateral crystal growth also proceeds on the surfaces of the respective ELO masks 4 each formed of a material other than GaN and the surface 1a of the substrate.

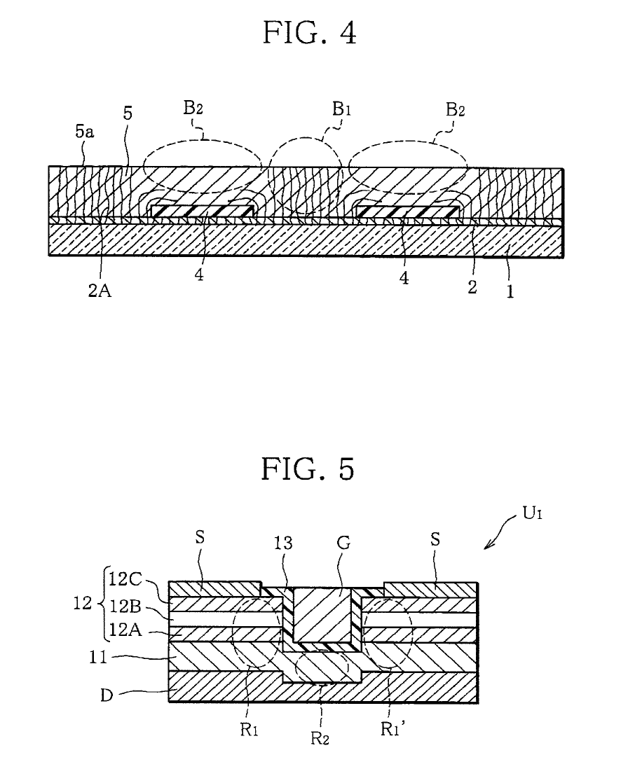

When the substrate A₁ is used, for instance, the thickness of a GaN crystal on a surface 2a of the GaN buffer layer 2 increases by vertical crystal growth, and at the same time, the top of each ELO mask 4 is progressively buried in the GaN crystal by lateral crystal growth. When the crystal growth is continued until a predetermined film thickness is obtained, lateral fusion between crystal layers on the ELO masks 4 and crystal layers on the surface 2a proceeds to form a GaN crystal layer 5 having a flat surface 5a, as shown in FIG. 4.

In the film-forming process, most threading dislocations 2A in the buffer layer extend continuously in the direction of film thickness in a propagating manner into portions of the GaN crystal layer grown vertically on the surface 2a of the buffer layer 2, whereas some threading dislocations 2A in the buffer layer extend into portions of the GaN crystal layer grown on the ELO masks 4, by changing their courses in lateral directions in accordance with lateral growth of the GaN crystal layer.

As a result, in the completely formed GaN crystal layer 5, on opposite sides of each ELO mask 4, there are GaN crystal regions B₁ each having a high dislocation density due to straight propagation of the aforementioned most threading dislocations extending upward from the buffer layer 2. On the other hand, immediately above the ELO masks 4, there are regions into which the aforementioned some threading dislocations extend from the buffer layer 2 in a manner bent laterally, and further above each of these regions, there is formed a high-quality GaN crystal region B₂ containing a sharply reduced number of threading dislocations.

In short, when epitaxial crystal growth is performed on the substrate A₁, portions of the completely formed GaN crystal layer located on the ELO masks are formed in a stripe pattern as high-quality GaN crystal regions each having a reduced dislocation density, while the other portions of the same are formed in a stripe pattern as GaN crystal regions each having a high dislocation density.

In this connection, when the substrate A₂ is used, GaN crystal layers each having a reduced dislocation density are formed in a stripe pattern on the surface la of the sapphire substrate 1.

In view of the behaviors of threading dislocations in a GaN crystal layer formed by the ELO technique, the present inventor has made the following prospects or considerations with a view to manufacturing a high-quality GaN FET:

(1) It is considered that when a GaN crystal layer is formed to have a thickness increased to some extent, even if the surface of the resulting GaN crystal layer may not be flat, an active layer for forming an FET thereon and a contact layer for forming each electrode thereon can be formed in a layered manner, which will make it possible to utilize the full potential of electrical characteristics that each layer is expected to have.

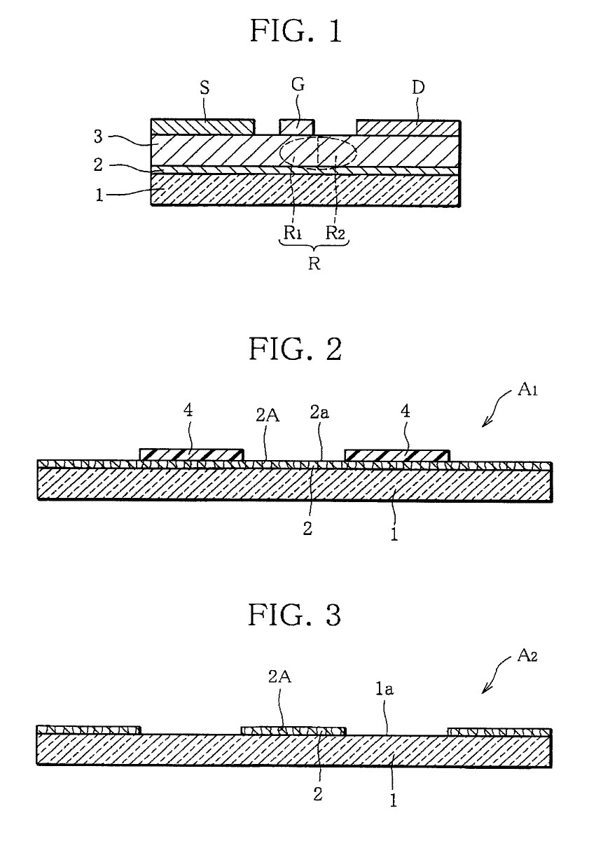

(2) In manufacturing a GaN FET having the structure shown in FIG. 1, if the substrate A₁ is used, the upper region B₂ formed above each ELO mask 4 is a high-quality GaN crystal region having a reduced dislocation density and hence having a high breakdown field. Therefore, it is considered that if an electrode, such as the gate electrode G, is formed on the region B₂, the FET thus obtained can utilize the full potential of intrinsic characteristics of the GaN crystal, whereby it is possible to enhance the breakdown voltage of the FET and reduce the amount of leakage current.

(3) Further, in this case, the regions B1 (whose dislocation density is high) and the regions B2 (whose dislocation density is low) indicated in FIG. 4 are formed on the surface of the complete GaN crystal layer, in a manner corresponding to the stripe pattern of the ELO masks 4. Therefore, it is expected that if the pattern of the ELO masks 4 of a desired design of an FET is formed in a manner corresponding to a pattern of electrodes, such as a source electrode and a gate electrode, which are to be formed, the layer structure 3 of a GaN crystal formed between these electrodes and the ELO masks will perform the functions described in the above prospect (2), effectively.

After carrying out various experiments based on the above prospects, the present inventor has completed the aforementioned FET (1) and FET (2).

In the following, the invention will now be described in detail with reference to drawings showing the GaN FET's and methods of manufacturing the same according to the present invention.

First, a description is made of the FET (1).

This FET has a layer structure of GaN crystals, described in detail hereinafter, with source electrodes and gate electrodes formed thereon, and a drain electrode formed in a lower surface thereof. In each region where a source electrode and a gate electrode are formed in a manner adjacent to each other, a channel can be formed and controlled by applying an electric field between the gate and source electrodes from the outside. In this case, the FET (1) is of a vertical current path type in which a region immediately under each source electrode and a region where a source electrode and a gate electrode are formed adjacent to each other function as the maximum electric field regions, and this type of FET is useful as a low ON-resistance switching transistor.

FIG. 5 shows a basic layer structure of a unit structure U₁ for the FET (1).

The unit structure U₁shown in FIG. 5 has a gate source G embedded therein. The unit structure U₁ is comprised of a layer structure 12 formed by providing an n-GaN crystal layer 12A, a p-GaN crystal layer 12B and an n-GaN crystal layer 12C, one upon another, on the surface of an n-GaN crystal layer 11 formed by a method described hereinafter, source electrodes S forming ohmic contacts to the n-GaN crystal layer 12C, the gate electrode G embedded in the layer structure 12 via an insulating film 13, and a drain electrode D formed directly on the lower surface of the layer structure 12, more specifically on the lower surface of the n-GaN crystal layer 11.

In the unit structure U₁, when a proper bias voltage is applied between the electrodes to cause the transistor to operate, the electric lines of force generally concentrate in regions each including a portion of the layer structure immediately under the corresponding source electrode S and a portion of the layer structure spreading from the portion immediately under the corresponding source electrode S toward the gate electrode G side, i.e. regions R₁, R₁′, each circled by a broken line in FIG. 5, though depending on the positional relationship in the lateral direction between the source electrode S and the gate electrode G. In the present specification, the region where the electric lines of force concentrate when a bias voltage is applied between electrodes is referred to as “the maximum electric field region”.

In the unit structure U₁ shown in FIG. 5, the regions R₁, R₁′ are the maximum electric field regions defined by the present invention. The unit structure U₁ is characterized in that the dislocation density in each of the regions R₁, R₁′ is lower than that of the other regions, e.g. that of the region R₂ appearing in FIG. 5.

The unit structure U₁ is manufactured by the following procedure, which will be described based on an example of a case in which a substrate A₁ of the type shown in FIG. 2 is used as a crystal-growing substrate.

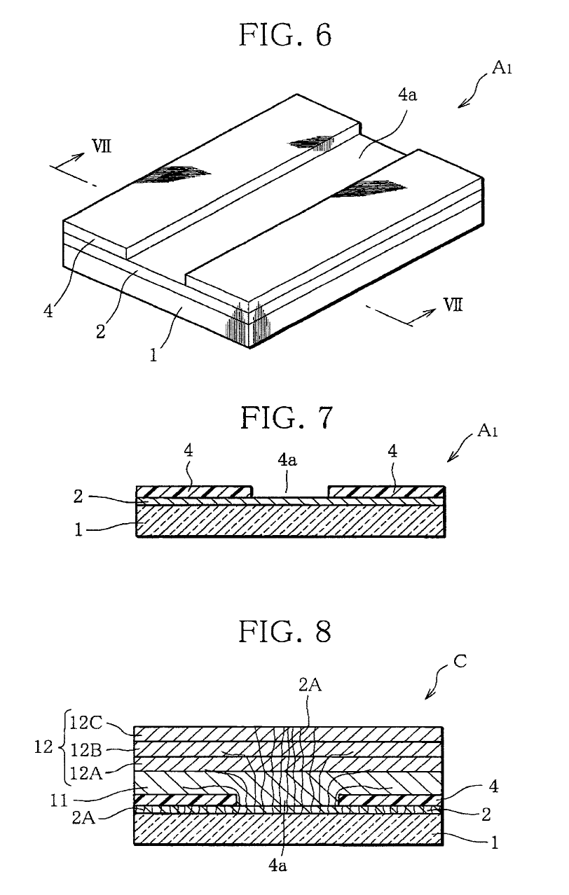

First, a GaN low-temperature deposition buffer layer 2 having a desired thickness is formed on a substrate 1 formed, for example, of a single crystal of sapphire. Further, a film, for example, of SiO₂ with a desired thickness is formed on the GaN buffer layer 2, and then the SiO₂ film is subjected to photolithography and etching to form a stripe-patterned ELO masks 4 defining an opening 4a having a predetermined width. Thus, the crystal-growing substrate A₁ shown in FIG. 7 is manufactured. FIG. 7 is a cross-sectional view taken on line VII-VII of FIG. 6.

The stripe pattern of the ELO masks 4 is required to be formed based on the following design criterion:

The stripe pattern of the ELO masks 4 is formed to have a shape identical to that of a pattern of source electrodes S to be formed on the upper surface of the unit structure U₁, shown in FIG. 5, or a shape slightly larger in width than the pattern of the source electrodes S. Therefore, in the case of FIG. 6, the pattern of the opening 4a defined by the ELO masks 4 is identical to that of a gate electrode G to be formed.

When the ELO technique is applied to manufacturing of the unit structure U₁ based on the above design criterion, it is possible to reduce the dislocation density of each portion of a GaN crystal layer grown on the ELO mask 4, thereby enhancing the breakdown field of the maximum electric field regions R₁, R₁′. Outside the design criterion, sufficient reduction of the dislocation density in the maximum electric field regions R₁, R₁′ cannot be realized, which makes it difficult to manufacture a high-performance FET.

To comply with the design criterion, it is only required to inscribe beforehand the surface of a substrate 1 to be used, with alignment marks representative of sites for forming source electrodes (operational electrode) S of a unit structure U1 to be manufactured.

Subsequently, a GaN crystal layer is formed on the crystal-growing substrate A₁ by the ELO technique.

First, a lateral crystal growth speed and a vertical crystal growth speed are set as desired, and an n-GaN crystal layer 11 formed, for example, of Si-doped GaN is formed, for example, by the MOCVD method. Then, an n-GaN crystal layer 12A formed, for example, of Si-doped GaN, a p-GaN crystal layer 12B formed, for example, of Mg-doped GaN, and an n-GaN crystal layer 12C formed, for example, of Si-doped GaN are sequentially formed on the n-GaN crystal layer 11, to form a layer structure 12 having a generally flat surface, whereby a slab substrate C as shown in FIG. 8 is manufactured.

The dislocation density in the formed layer structure 12 is high in a region above the opening 4a defined by the ELO masks, into which threading dislocations 2A extend upward from the low-temperature deposition buffer layer 2 in a propagating manner without changing their courses, and low in regions above the ELO masks 4, where most threading dislocations are bent laterally. That is, the high quality of the GaN crystal is maintained in the regions of the layer structure above the ELO masks 4, i.e. the regions immediately under the respective source electrodes to be formed.

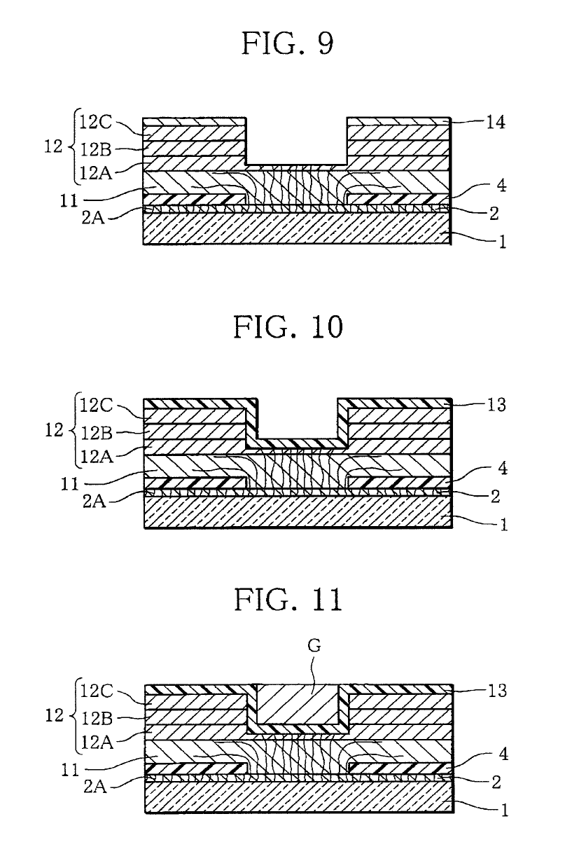

Subsequently, after forming a film 14, for example, of SiO₂ on the whole upper surface of the slab substrate C, a portion of the SiO₂ film where the gate electrode is to be formed is patterned with reference to the alignment marks, and only the patterned portion of the SiO₂ film is removed by etching. Then, by using the remaining portions of the SiO₂ film 14 as ELO masks, the exposed portion of the layer structure 12 is removed, for example, by reactive ion beam etching (RIBE) to thereby form a trench structure having a depth which reaches part of the n-GaN crystal layer 12A (see FIG. 9).

Thereafter, the SiO₂ film 14 is removed by etching, and then a film, for example, of AlN or AlGaN is formed as an insulating film 13 by the MOCVD method on the whole upper surface of the substrate including the surface of the trench (see FIG. 10). Further, a material (e.g. WSi) for forming the gate electrode is deposited on the whole upper surface of the substrate by the CVD method or the like to fill the trench structure, and then the material deposited on the other areas than the trench structure is removed by chemical-mechanical polishing (CMP). Thus, the gate electrode G appearing in FIG. 11 is formed.

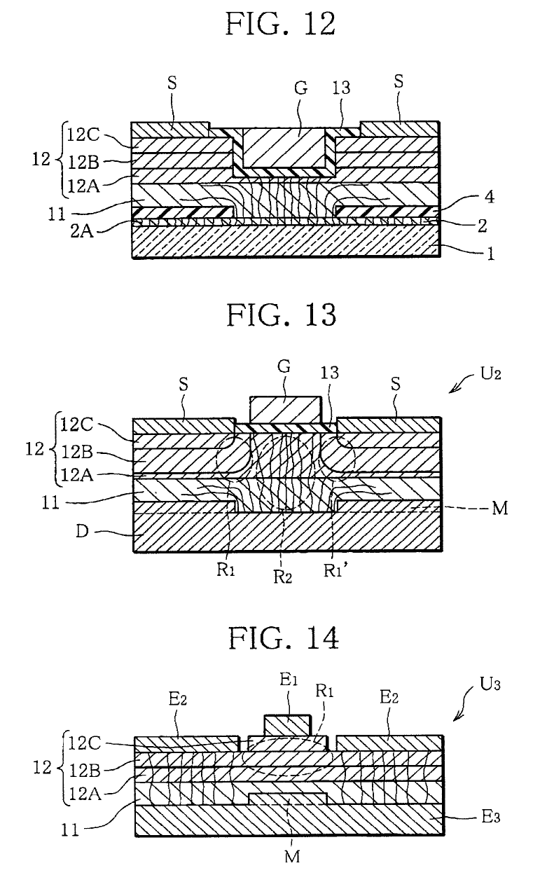

Subsequently, after forming a film, for example, of SiO₂ on the whole upper surface of the slab substrate C, portions in which the respective source electrodes are to be formed are patterned with reference to the alignment marks, and only the patterned portions of the SiO₂ film are removed by etching. Then, by using the remaining portion of the SiO₂ film 14 as the ELO masks, exposed portions of the insulating film 13 are removed by etching, and further, films of a material (e.g. Al/Ti/Au) for forming each source electrode are formed on the respective portions by spattering or the like. Thus, the source electrodes S are formed on the layer structure 12, as shown in FIG. 12.

Finally, after removing the sapphire single-crystal substrate 1 at the bottom by excimer laser irradiation, the low-temperature deposition buffer layer 2 is removed by dry etching and the ELO masks 4 by hydrofluoric acid, to thereby cause the lower surface of the n-GaN crystal layer 11 to be exposed to the outside, followed by forming a film of Al/Ti/Au or the like on the exposed surface by spattering to form the drain electrode D.

Since the unit structure U₁ shown in FIG. 5 is manufactured by the steps described above, the maximum electric field regions R₁, R₁′ are formed at respective locations above the ELO masks 4, where the dislocation density in the GaN crystals is reduced during crystal growth, so that the regions R₁, R₁′ are formed of high-quality GaN crystals, which enhances the breakdown voltage between the source electrodes S and the drain electrode D.

It should be noted that although the dislocation density immediately under the gate electrode G is high, the insulating film 13 maintains insulation between the gate electrode G and the drain electrode D.

FIG. 13 shows a basic layer structure of a unit structure U₂ as an example of a unit structure of a vertical MISFET belonging to the family of the FET (1).

In manufacturing the unit structure U₂, portions of the slab substrate C in FIG. 8 other than a region of the layer structure above the opening 4a defined by the ELO masks are once removed by etching, and then a layer structure 12 having an n-GaN crystal layer 12A, a p-GaN crystal layer 12B, and an n-GaN crystal layer 12C are formed by a regrowth process in each region where the former layer structure was removed by etching. Subsequently, source electrodes S, S are formed on the newly formed layer structure 12, while a gate electrode G is formed on the unremoved portion of the former layer structure via the insulating film 13. Further, a drain electrode D is formed on the lower surface of the n-GaN crystal layer 11.

Similarly to the unit structure U₁, the unit structure U₂ has regions R₁, R₁′ appearing in FIG. 13 as the maximum electric field regions. During crystal growth of the GaN crystals, each of the regions R₁. R₁′ was also located above the corresponding ELO mask 4, i.e. above a site M where the ELO mask 4 existed, so that the dislocation density of threading dislocations in the region R₁ (R₂) is low, and hence the unit structure U₂ is also capable of exhibiting a high breakdown field.

FIG. 14 shows a basic layer structure of a unit structure U₃ as an example of a unit structure of a bipolar transistor belonging to the family of the FET (1).

This unit structure U₃ shows a case in which crystal growth of GaN crystals is performed by the ELO technique, an ELO mask 4 of the substrate A₁ exists at a site M in an n-GaN crystal layer 11. The unit structure U₃ is comprised of a layer structure 12 formed by an n-GaN crystal layer 12A, a p-GaN crystal layer 12B, and an n-GaN crystal layer 12C, deposited one upon another, on the n-GaN crystal layer 11, an emitter electrode E₁ formed on the n-GaN crystal layer 12C, a base electrode E₂ formed on the p-GaN crystal layer 12B, and a collector electrode E₃ formed on the lower surface of the n-GaN crystal layer 11.

The unit structure U₃ has a region R₁ appearing in FIG. 14 as the maximum electric field region. The region R₁ is located above the site M where the ELO mask 4 existed during GaN crystal growth by the ELO technique, so that the dislocation density of threading dislocations in the region R₁ is low, and hence the unit structure U₃ is also capable of exhibiting a high breakdown field.

Next, the FET (2) according to the present invention will be described.

The FET (2) is a horizontal current path GaN FET having all electrodes, such as source electrodes, gate electrodes and drain electrodes, formed on a layer structure of GaN crystals, described in detail hereinafter, and having regions including a region immediately under each gate electrode and a region adjacent thereto and spreading toward the drain electrode side as the maximum electric field regions.

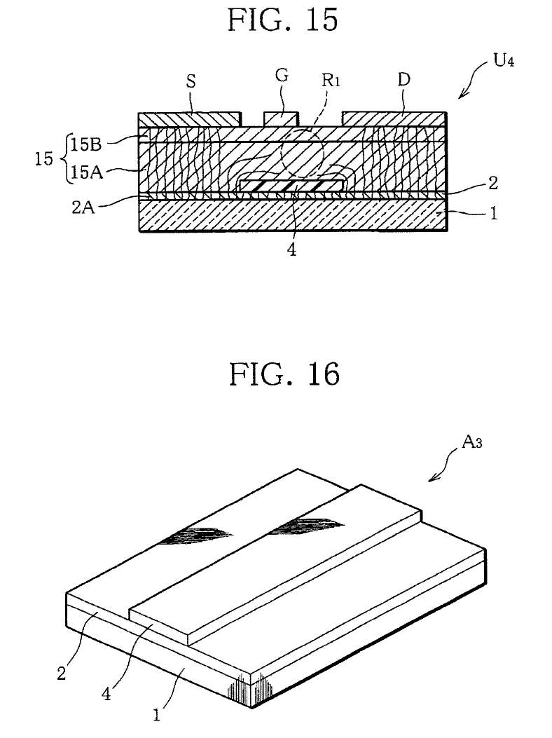

FIG. 15 shows a basic layer structure of a unit structure U₄ of the FET (2).

The unit structure U₄ shown in FIG. 15 has a layer structure of an MESFET type having a GaN low-temperature deposition buffer layer 2 formed on a substrate 1, and an ELO mask 4, referred to hereinafter, formed on the buffer layer 2.

Further, the unit structure U₄ is comprised of a layer structure 15 formed by a high-resistance GaN crystal layer 15A, for example, of an undoped GaN crystal or p-GaN crystal and a conductive GaN crystal layer 15B of an n-GaN, deposited one upon the other, and operational electrodes, such as a source electrode S, a gate electrode G, and a drain electrode D, formed on the layer structure 15.

When the unit structure U₄ is operated, a region including a region immediately under the gate electrode G and a region adjacent thereto and spreading toward the drain electrode side, i.e. a region R₁ circled by a broken line in FIG. 15 becomes the maximum electric field region.

Therefore, in the unit structure U₄, a portion of the layer structure 15 including the region R₁, i.e. a portion of the layer structure 15 above the ELO mask 4 is required to have a lower dislocation density of threading dislocations 2A than the other portions of the layer structure 15, such as a region immediately under the source electrode S or the drain electrode D. If the dislocation density in the region R₁ were high, the unit structure U4 could not exhibit an excellent breakdown field strength.

In forming the layer structure 15 of the unit structure U₄, the ELO technique using a crystal-growing substrate A₃ shown in FIG. 16 is employed.

A crystal-growing substrate A₃ shown in FIG. 16 is distinguished from the substrate A₁ of the FIG. 2 type, in that a stripe pattern of the ELO mask 4 is formed in a manner corresponding to a pattern of the gate electrode to be formed. More specifically, the stripe pattern has a stripe positioned at the same location where the gate electrode is formed and having a larger width in cross-section than the gate electrode G.

Still more specifically, the crystal-growing substrate A₃ has the stripe pattern of the ELO mask designed such that a region which will serve as the maximum electric field region R₁ in the manufactured unit structure U₄ can be located above the ELO mask 4 and portions of the low-temperature deposition buffer layer 2 on the opposite sides of the ELO mask 4 are exposed.

When the ELO technique is applied to the crystal-growing substrate A₃, threading dislocations 2A extend upward from the buffer layer 2 in a propagating manner into portions of the layer structure 15 formed on both sides of the ELO mask 4 without changing their courses, whereas some threading dislocations 2A extend from the same in a manner bent laterally into a portion of the layer structure 15 formed above the ELO mask 4. As a result, the layer structure has a lower dislocation density in a region above the ELO mask 4 than in regions above the buffer layer 2 on both sides of the mask 4. Further, by adjusting the whole film thickness, the layer structure 15 can be formed such that it has an upper surface made flat enough for electrodes to be formed thereon.

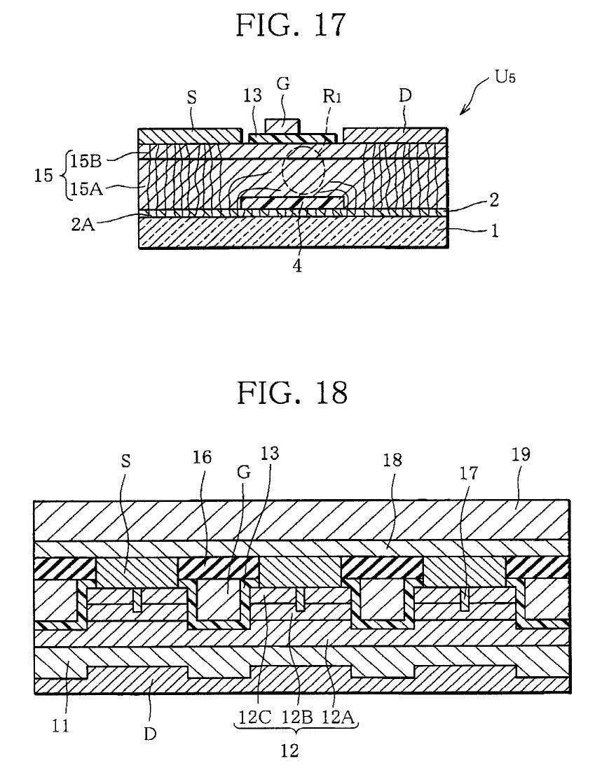

FIG. 17 shows a basic layer structure of a unit structure Us as an example of a unit structure of a lateral HEMT or MISFET belonging to the family of the FET (2).

The unit structure U₅ has a gate electrode G formed on a portion of a layer structure 15 above an ELO mask 4 via an insulating film 13 formed, for example, of AlN or AlGaN. When the unit structure U₅ is operated, a region R₁ becomes the maximum electric field region.

The layer structure 15 of the unit structure U₅ is formed by the ELO technique using the crystal-growing substrate having the ELO mask stripe pattern shown in FIGS. 15 and 16. Therefore, since the dislocation density in the region R₁ is low, the layer structure 15 is capable of exhibiting a high breakdown field as an FET.

Example 1

A vertical GaN FET device having a structure shown in cross section in FIG. 18 and low ON-resistance characteristics was designed as an example of the FET (1) according to the present invention.

The designed device is comprised of a GaN crystal layer structure 12 formed of an n-GaN crystal layer 12A, a p-GaN crystal layer 12B, and an n-GaN crystal layer 12C, gate electrodes G each having a width of 1 μm and embedded in the layer structure 12 via respective AlN insulating films 13 at space intervals of 5 μm in a state of an upper portion of each gate electrode G being sealed by an SiO₂ insulating film 16, turn-off junctions 17 each formed in the layer structure 12 for removing electrons poured into the p-GaN layer 12B, thereby shortening a time period required for switching operation, source electrodes S each formed on the layer structure 12, a source metal 18 and a heat sink 19 formed to cover the whole upper surface of the device, and a drain electrode D formed on the lower surface of the layer structure 12 via an n-GaN crystal layer 11.

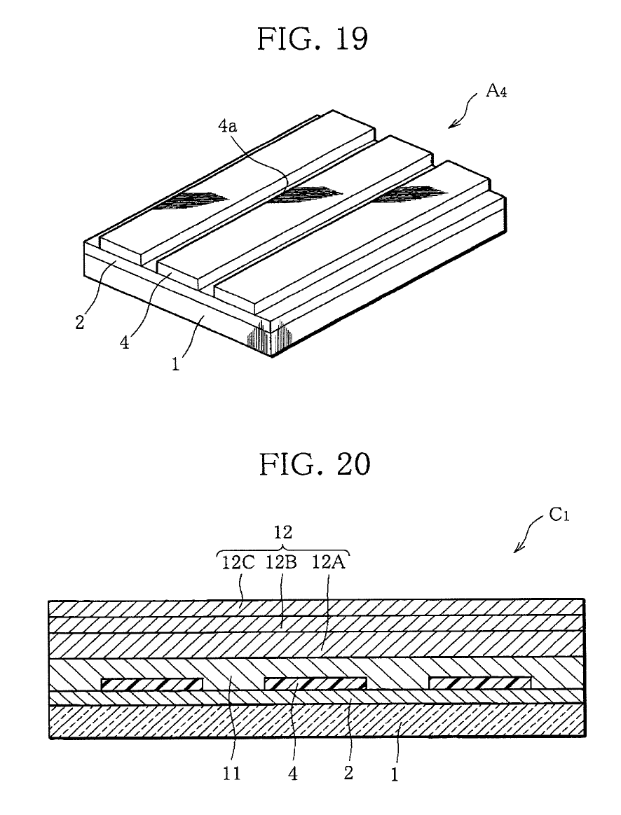

Before manufacturing of the above designed device, first, a crystal-growing substrate A₄ shown in FIG. 19 was prepared. The crystal-growing substrate A₄ is comprised of a sapphire single-crystal substrate 1, a GaN low-temperature deposition buffer layer 2 having a thickness of 0.05 μm formed on the substrate 1, and ELO masks 4 of SiO₂ having a thickness of 0.1 μm and formed on the layer 2 in a stripe pattern.

The ELO masks 4 are formed at space intervals of 6 μm in a manner corresponding to the respective layer structures of the designed device, and the width of a opening 4a formed between each two of the ELO masks 4a is set to 2 μm which is the same width as that of each gate electrode G.

After inscribing alignment marks representative of the positions of respective source electrodes S to be formed on the crystal-growing substrate A₄, first, under film-forming conditions for making the speed of lateral crystal growth five times higher than that of vertical crystal growth, ELO was carried out by the MOCVD method such that vertical film thickness was increased to 1 μm, to thereby form an Si-doped GaN crystal layer 11.

Thus, the Si-doped GaN crystal layer 11 was formed to have a film thickness of 1 μm on each opening 4a and a film thickness of approximately 0.5 μm on each surface of the ELO mask 4.

Then, an Si-doped GaN crystal layer 12A, for example, having an Si concentration of 1.5×10¹⁷ cm⁻³ and a thickness of 1 μm, and using Mg as an acceptor, an Mg-doped GaN crystal layer 12B formed and, for example, having a hole concentration of 2×10¹⁷ cm⁻³ and a thickness of 0.3 μm, and an Si-doped GaN crystal layer 12C, for example, having an Si concentration of 1×10¹⁹ cm⁻³ and a thickness of 0.5 μm were sequentially deposited, one upon another, on the Si-doped GaN crystal layer 11 by the MOCVD method, whereby a slab substrate C₁ as shown in FIG. 20 was manufactured.

In the slab substrate C₁ shown in FIG. 20, the surface of the uppermost Si-doped GaN crystal layer 12C was generally flat with asperities of approximately 0.1 μm left partially.

Further, in the slab substrate C₁, the dislocation density in the layer structure 12 was lower at a location above each ELO mask 4 than at a location above each opening 4a of an ELO mask. It was found by observation of the layer structure formed under the above conditions, using a plane transmission electron microscope (TEM), that the threading dislocation density is approximately 1×10⁷ cm⁻² above each ELO mask 4 and approximately 1×10¹⁰ cm⁻² above each opening 4a, which clearly proves significant difference in dislocation density within the layer structure 12.

Next, the slab substrate C₁ was processed to manufacture an FET.

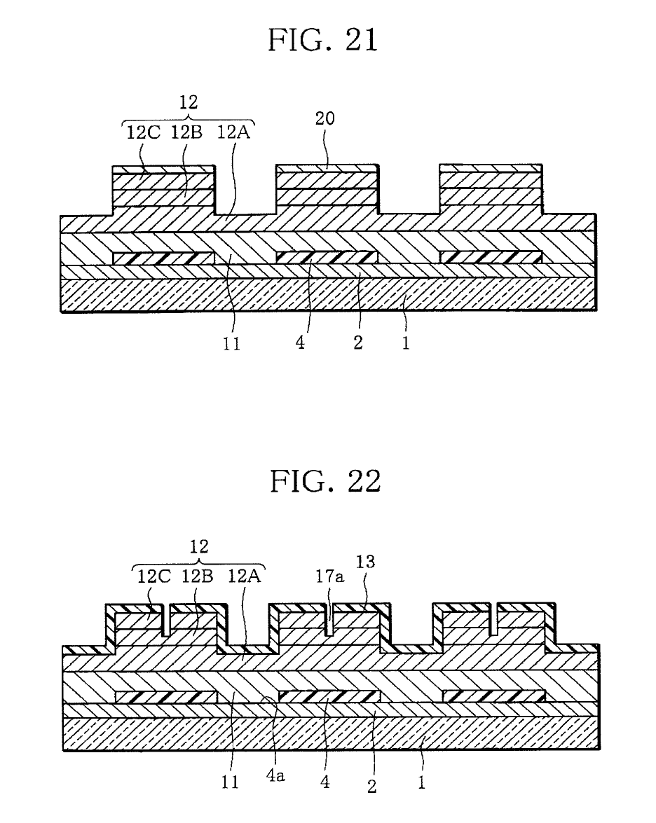

First, an SiO₂ film 20 having a thickness, for example, of 0.2 μm was formed on the whole upper surface of the slab substrate C₁. Then, with reference to the aforementioned alignment marks a portion for forming a gate electrode thereon was patterned, and the patterned portions of the SiO₂ film were removed by wet etching to thereby cause the corresponding portions of the surface of the uppermost Si-doped GaN layer 12C to be exposed. Further, by using the remaining portions of the SiO₂ film 20 as the ELO masks, the exposed portions of the layer structure 12 were removed by etching by RIBE to form trench structures each having a depth of 1 μm as shown in FIG. 21.

Subsequently, the SiO₂ film 20 was removed by wet etching. Then, a film, for example, of AlN having 0.05 μm was formed on the whole upper surface of the substrate by the MOCVD method to form an insulating film 13. Further, an SiO₂ film having a thickness of 0.2 μm was formed on the whole surface of the insulating film 13. Thereafter, portions for forming respective turn-off junctions therein were patterned, and the patterned portions of the SiO₂ film were removed to cause the corresponding portions of the surface of the insulating film 13 to be exposed. Then, by using the remaining portions of the SiO₂ film as ELO masks, trenches each having a depth of 0.6 μm and extending downward to the Mg-doped GaN crystal layer 12B were formed by RIBE as windows 17a for the respective turn-off junctions, and the SiO₂ film used as the ELO masks were removed by wet etching. As a result, a substrate shown in cross section in FIG. 22 could be obtained.

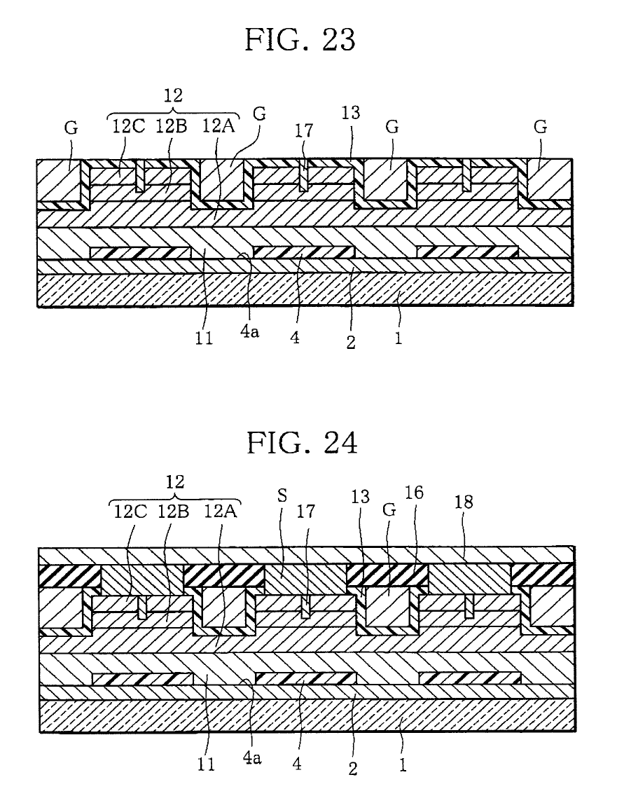

Then, WSi, for example, was deposited on the upper surface of the substrate by the CVD method to fill the above two kinds of trenches, whereby the gate electrodes G and the turn-off junctions 17 were formed as shown in FIG. 23. Excess WSi deposited on the surface of the substrate was removed by dry etching. It goes without saying that other CMP methods can be applied to removal of the excess WSi.

Subsequently, an SiO₂ film was formed on the whole upper surface of the FIG. 23 substrate, and then the whole substrate was subjected to heating treatment in a N₂ atmosphere with a temperature of 850° C. for thirty minutes for activation of the acceptor (Mg) in the Mg-doped GaN crystal layer 12B as well as for recovery of the substrate from damage due to the dry etching effected on the substrate surface at the preceding step.

Thereafter, portions of the surface of the SiO₂ film covering sites where respective source electrodes are to be formed were subjected to patterning. Then, the SiO₂ film was removed from each of the sites to form a contact hole. Continuously, the AlN insulating film 13 on each of the sites was removed by alkaline wet etching, and Al/Ti/Au was deposited on the hole portion by spattering to form a source electrode S. Further, a source metal 18 formed of Ti/Au was formed on the whole upper surface of the substrate by spattering.

As a result, the gate electrodes G and the source electrodes S were formed, as shown in FIG. 24, such that each gate electrode G and the corresponding source electrode S were separated from each other by the SiO₂ film 16. The gate electrodes G are each connected to gate electrode pads at the opposite sides thereof.

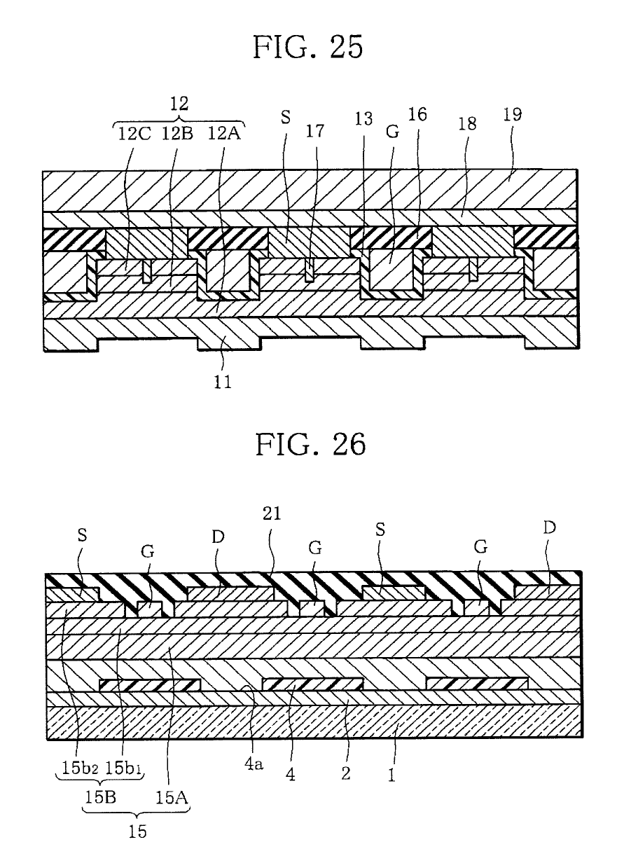

Then, a heat sink 19 for the source electrodes S was soldered to the source metal 18 in a manner covering the whole surface of the same, whereby the mechanical strength of the source electrodes S is secured. Then, the sapphire single-crystal substrate 1 was irradiated with excimer laser from below to be stripped for removal. Further, the GaN low-temperature deposition buffer layer 2 and the ELO masks 4 were sequentially stripped for removal by RIBE and hydrofluoric acid, to thereby cause the lower surface of the Si-doped GaN crystal layer 11 to be exposed as shown in FIG. 25.

Finally, a film of Al/Ti/Au was formed on the exposed surface of the Si-doped GaN crystal layer 11 by spattering to form a drain electrode D. Thus, the designed device shown in FIG. 18 was manufactured.

The vertical FET showed an enough breakdown voltage to withstand a voltage of more than 100 V between the source electrodes S and the drain electrodes D, and had an ON resistance of 1 mΩ for an effective gate width of 50 cm. That is, the FET had excellent breakdown field and switching characteristics.

Example 2

A lateral GaN FET device having a structure shown in cross section in FIG. 26 was designed as an example of the FET (2) according to the present invention.

According to the designed device, a GaN crystal layer structure 15 is comprised of a high-resistance GaN crystal layer 15A formed of Mg-doped GaN, and a conductive GaN crystal layer 15B formed of Si-doped GaN. The conductive GaN crystal layer 15B is comprised of an Si-doped GaN crystal layer 15b₁ serving as a channel layer and an Si-doped GaN crystal layer 15b₂ serving as a contact layer for contact between source electrodes S and drain electrodes D. The space between each source electrode S and a neighboring drain electrode D is set to 3 μm, and a gate electrode G having a width of 0.5 μm is disposed therebetween. The whole upper surface of the device is protected by an SiO₂ film 21.

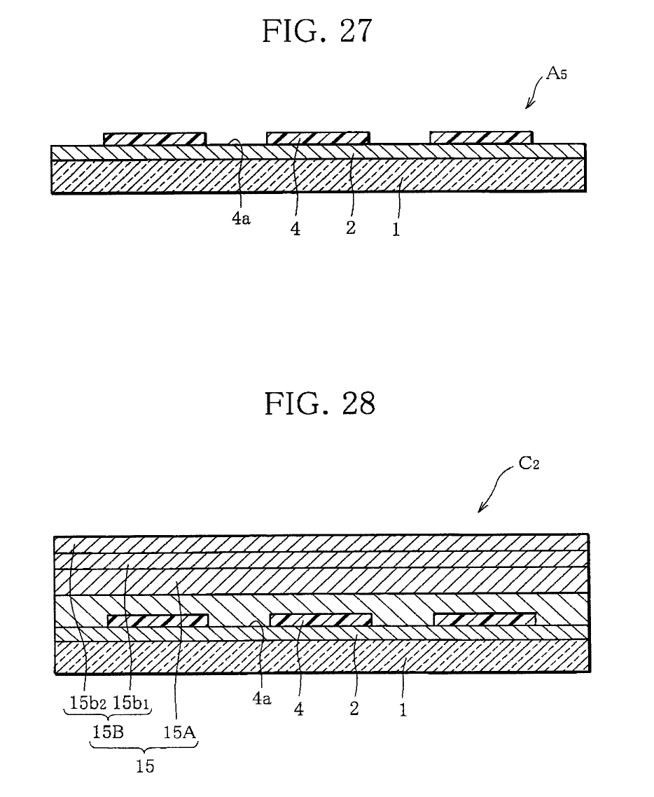

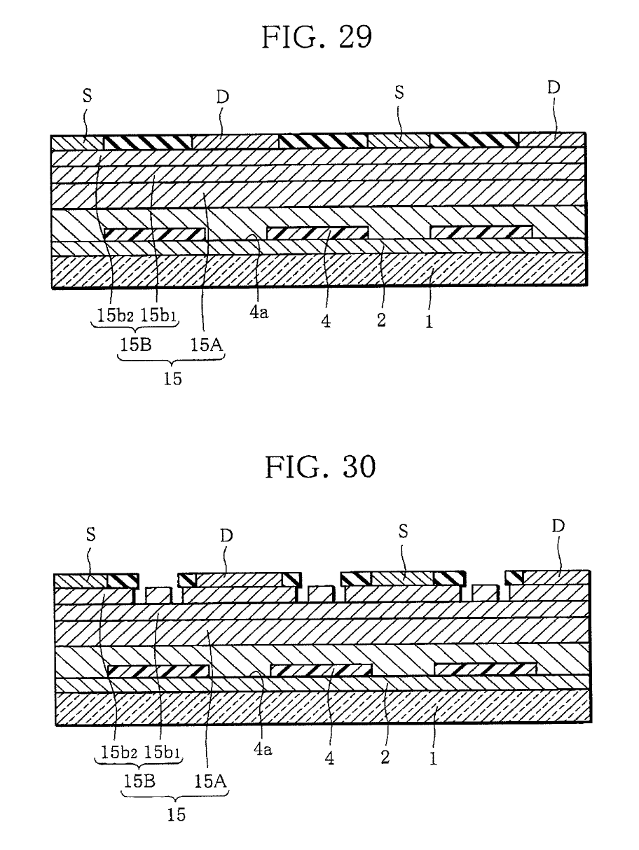

Before manufacturing of the above designed device, first, a crystal-growing substrate A₅ shown in FIG. 27 was prepared. The crystal-growing substrate A₅ is comprised of a sapphire substrate 1, a GaN low-temperature deposition buffer layer 2 with a thickness of 0.05 μm formed on the substrate 1, and ELO masks 4 of SiO₂ with a thickness of 0.1 μm formed on the layer 2 in a stripe pattern.

The ELO masks 4 are formed at space intervals of 20 μm in a manner corresponding the respective locations of gate electrodes G of the designed device, and the width of a opening 4a formed between each adjacent pair of the ELO masks 4a is set to 16 μm.

After inscribing alignment marks representative of the positions of the respective gate electrodes G to be formed on the crystal-growing substrate A₅, first, under film-forming conditions for making the speed of lateral crystal growth five times higher than that of vertical crystal growth, ELO was carried out by the MOCVD method such that vertical film thickness is increased to 2 μm, to thereby form an Mg-doped GaN crystal layer 15A.

Thus, the Mg-doped GaN crystal layer 15A was formed to have a film thickness of 2 μm on each opening 4a and a film thickness of approximately 1.8 μm on each ELO mask 4.

Then, an Si-doped GaN crystal layer 15b₁ having an Si concentration of 5×10¹⁷ cm⁻³ and a thickness of 0.2 μm and an Si-doped GaN crystal layer 15b₂ having an Si concentration of 5×10¹⁸ cm⁻³ and a thickness of 0.1 μm were sequentially deposited by the MOCVD method, one upon the other, on the Mg-doped GaN crystal layer 15A to thereby produce a slab substrate C₂ shown in FIG. 28.

In the slab substrate C₂ in FIG. 28, the surface of the uppermost Si-doped GaN crystal layer 15b₂ was generally flat with asperities of approximately 0.1 μm left partially.

Further, in the slab substrate C₂, the dislocation density in the layer structure 15 was lower at a location above each ELO mask 4 than at a location above each opening 4a of the ELO mask. For example, it was found by observation of the layer structure formed under the above conditions, using a plane transmission electron microscope (TEM), that the threading dislocation density is approximately 1×10⁷ cm⁻² above each ELO mask and approximately 1×10¹⁰ cm⁻² above each opening 4a, which clearly proves significant difference in dislocation density.

Next, the slab substrate C₁ was processed to manufacture the designed FET.

First, an SiO₂ film having a thickness, for example, of 0.2 μm was formed on the whole upper surface of the slab substrate C₂. Then, with reference to the aforementioned alignment marks, all portions for forming respective source and drain electrodes thereon were patterned, and the patterned portions of the SiO₂ film were removed by dry etching to thereby cause the corresponding portions of the surface of the uppermost Si-doped GaN layer 15b₂ to be exposed. Further, the exposed portions of the uppermost Si-doped GaN layer 15b₂ were coated with Al/Ti/Au by spattering, and then by lift-off, the source electrodes S and the drain electrodes D were formed on the Si-doped GaN layer 15b₂.

Subsequently, a site where a gate electrode was to be formed was patterned on an SiO₂ film portion between each source electrode S and its neighboring drain electrode D by electron beam lithography apparatus, to thereby cause the corresponding portions of the surface of the Si-doped GaN layer 15b₂ to be exposed. Then, by using the remaining portions of the SiO₂ film as ELO masks, the exposed portions were subjected to recess etching by RIBE to thereby cause the corresponding portions of the surface of the Si-doped GaN layer 15b₁ to be exposed. Thereafter, the exposed portions of the Si-doped GaN layer 15b₁ were coated with Pt/Ti/Au by EB deposition and then by lift-off, the gate electrodes G were formed on the Si-doped GaN layer 15b₁ in the designed pattern as shown in FIG. 30.

Finally, an SiO₂ film 21 was formed on the whole lower surface of the substrate, whereby the horizontal FET shown in FIG. 26 was completed.

The horizontal FET showed an enough breakdown field strength to withstand a voltage of 300 V or more, and had a cutoff frequency of 30 GHz. That is, the FET had excellent characteristics as a transistor for high-frequency amplification.

As is apparent from the above description, since the GaN FET according to the present invention is manufactured by the ELO technique, it is possible to set the stripe pattern of the ELO masks on the crystal-growing substrate to be used for manufacturing the GaN FET in accordance with a designed pattern of regions where electric lines of force concentrate during operation of the FET. Therefore, dislocation density of threading dislocations in the maximum electric field regions formed in the GaN crystal layer can be reduced, whereby the quality of the GaN crystal layer is enhanced.

Thus, in the GaN FET according to the present invention, a portion of the GaN crystal layer immediately under each operational electrode and a portion of the same adjacent thereto are more excellent in quality than those in the conventional GaN FET, and hence the potential of characteristic features of a GaN crystal can be drawn and utilized properly, which largely improves, for example, the breakdown voltage of the FET.

What is claimed is:

1. A GaN field-effect transistor comprising:
a plurality of GaN epitaxial crystal layers in a layer structure; and
at least electrodes necessary for operation of said field-effect transistor being disposed on a surface of said layer structure,
wherein said layer structure has a region having a reduced dislocation density compared with other regions, said region forming the maximum electric field region during operation of said field-effect transistor.

2. The GaN field-effect transistor according to claim 1, wherein a source electrode and a gate electrode are formed on said surface of said layer structure, and a drain source is formed on a reverse surface of said layer structure, at least a region in said layer structure immediately under said source electrode being formed to have a decreased dislocation density, in said layer structure of GaN epitaxial layer structure, compared with other regions in said layer structure.

3. The GaN field-effect transistor according to claim 1, wherein a source electrode, a gate electrode, and a drain source are formed on said upper surface of said layer structure thereon, at least a region in said layer structure immediately under said gate electrode being formed to have a decreased dislocation density, in said layer structure of GaN epitaxial layer structure, compared with other regions in said layer structure.

4. A method of manufacturing a GaN field-effect transistor, comprising the steps of:
forming a plurality of GaN epitaxial crystal layers, one upon another, on a surface of a crystal-growing substrate by using an epitaxial lateral overgrowth technique, thereby forming a layer structure partially including a region having a decreased dislocation density; and
disposing an electrode that enables operation of said field-effect transistor and at the same time determines the maximum electric field region wherein the electric lines of force concentrate during operation of said field-effect transistor, on a surface of said layer structure in a manner such that said region having a decreased dislocation density and said maximum electric field region coincide with each other,
wherein a mask for epitaxial lateral overgrowth is formed on said surface of said crystal-growing substrate, said mask being formed of a material other than a GaN-based material, with a design pattern identical to a configuration pattern of said electrode.

5. The method according to claim 4, including the steps of:
forming a source electrode and a gate electrode on said surface of said layer structure;
stripping said crystal-growing substrate from said layer structure, thereby causing the laser beam exposure on a reverse surface of said layer structure; and
forming a drain electrode on said exposed reverse surface of said layer structure removed the substrate.
